(19) United States
(12) Patent Application Publication
(10) Pub. No.: US 2008/0025080 A1
(43) Pub. Date: Jan. 31, 2008

(54) Method and apparatus for programming phase change devices

(75) Inventors: Vei-Han Chan, San Jose, CA (US); Louis Kordus, Sunnyvale, CA (US); Narbeh Derhacobian, Belmont, CA (US); Jason Golbus, Campbell, CA (US)

Correspondence Address: PATENT LAW PROFESSIONALS, P.O. BOX 612407, SAN JOSE, CA, 95161, US

(73) Assignee: Cswitch Corporation

(21) Appl. No.: 11/494,413

(22) Filed: Jul. 27, 2006

(51) Int. Cl. G11C 11/00

(52) U.S. Cl. 365/163

(57) ABSTRACT

Methods and apparatus for programming a phase change device (PCD) to a low resistance state. According to an exemplary method, one or more first programming pulses having a predetermined magnitude and/or duration are applied to a PCD. After each programming pulse is applied, the programmed resistance of the PCD is compared to a target resistance specification. If the programmed resistance is not in accordance with the target resistance specification, one or more second programming pulses having a magnitude and/or duration different than the magnitude and/or duration of the one or more first programming pulses are applied to the PCD. This process is repeated until the programmed resistance of the PCD satisfies the target resistance specification or it is determined that the PCD cannot be programmed to a resistance value that satisfies the target resistance specification.

### FIELD OF THE INVENTION

The present invention relates to phase change devices. More specifically, the present invention relates to methods and apparatus for programming phase change devices to a low resistance state.

### BACKGROUND OF THE INVENTION

Phase change materials are a class of “chalcogenic” compounds that are capable of changing between crystalline and amorphous states when exposed to appropriate thermal treatment processes. Chalcogenic compounds contain one or more of the chalcogen elements in Group VI of the periodic table, e.g., sulphur (S), selenium (Se) and tellurium (Te). They may also contain other or additional elements from Groups IV and V of the periodic table, e.g., germanium (Ge) and arsenic (As). When a phase change material is heated above its melting point, and then abruptly cooled, the phase change material solidifies to an amorphous state. Conversely, when heated above its melting point, and then allowed to gradually cool, the phase change material solidifies to a crystalline state.

A phase change material also exhibits different electrical and optical properties when in its crystalline state, compared to when in its amorphous state. These state-dependent electrical and optical properties can be exploited to realize a variety of applications. For example, phase change materials are currently being used to implement the digital storage elements in rewritable compact disks (CDs) and digital video disks (DVDs). Digital “1s” and “0s” are stored on a disk by directing a laser beam onto predetermined storage elements patterned on the disk. The laser beam introduces heat into the phase change material of the elements, and is controlled so that the storage elements are programmed to either the crystalline state or the amorphous state. Different refractive indexes of the resulting crystalline and amorphous states are used to distinguish between the digital “1s” and “0s”, when the disk is read.

Phase change materials have also recently been utilized to implement solid state memory. In addition to the benefits of being reversibly programmable, an added benefit of implementing memory devices using phase change materials is that the memory devices are nonvolatile, meaning that the memory retains its programmed state even in the absence of power. Integrated circuit (IC) memory devices using phase change material devices (PCDs) are typically configured as a plurality of memory cells formed in an array, similar to the manner in which conventional memory ICs are configured. Each cell of the array includes one or more PCDs that can be programmed to either crystalline or amorphous states. As shown in FIG. 1, each PCD 10 of a memory cell typically includes a heater element 100 attached to a first terminal 102 of the device 10. The heater element 100 is configured so that it is in physical contact with a phase change material 104 attached to a second terminal 106 of the device 10. A particular memory cell of the memory array is programmed to a digital “1” or “0” by first selecting the desired memory cell in a manner similar to that used for conventional memory arrays. Electrical currents are then directed through the phase change material of the PCD of the selected memory cell. The currents cause the heater element 100 to generate joule heat, which is conducted to the phase change material of the PCD. By carefully controlling the electrical currents, the phase change material of the selected PCD can be set to a crystalline state or an amorphous state.

As shown in FIG. 2, a phase change material exhibits a different electrical resistance, depending on whether it is in its crystalline state or is in its amorphous state. Hence, a PCD can be viewed as a programmable resistor, which is capable of storing a digital “1” or “0” depending on whether the phase change material of the PCD has “set” to a crystalline low resistance state or has been “reset” to an amorphous high resistance state.

There are various known prior art references disclosing methods for programming PCDs. U.S. Pat. No. 6,075,719 to Lowrey et al. (hereinafter referred to as “the '719 patent”), for example, discloses a method of programming phase change devices of a memory to low resistance states. As shown in FIG. 3A here, the '719 patent method first directs a first rectangular current pulse (I_{RESET} or “reset” pulse) through a selected memory device, so that the device is transformed from a crystalline low resistance state to an amorphous high resistance state. Subsequently, a second rectangular current pulse (I_{SET} or “set” pulse) is directed through the selected memory device, so that the device is set to the desired crystalline low resistance state.

Because of fabrication and material variations during processing, the temperature at which the phase change material rises during programming also varies. If, in a given device, the temperature rises higher than the amorphizing temperature Tₘ during application of the set pulse, the given memory device could erroneously remain in the amorphous high resistance state, rather than being programmed to the intended crystalline low resistance state. To avoid this problem, the '719 patent suggests lowering the magnitude of the set pulse so that the device temperature of all devices is guaranteed not to reach the amorphizing temperature Tₘ during the time the set pulse is applied. To compensate for the less than optimal temperatures generated by the reduction in set pulse magnitude, the duration of the set pulse is also lengthened with the object of ensuring adequate heating of the phase change material. While the solution disclosed in the '719 patent does help to ensure that the temperatures of all memory devices of the memory do not exceed the amorphizing temperature Tₘ during the set operation, the proposed solution has various drawbacks.

First, the increased duration of the set pulses slows down the programming speed of the memory. Second, the solution does not guarantee that each of the cells of the memory receives a current resulting in the cell's optimum crystallization temperature. Failing to address this problem not only results in a reduction in dynamic range of low and high resistance devices, it also results in a wide variation in low resistance values among the plurality of memory devices making up the memory. Third, because the memory devices across a wafer or die typically have varying programming properties caused by fabrication process and material variations, the fixed-magnitude set pulse is incapable of programming all devices to the intended low resistance state. As shown in FIG. 4, for example, a low-magnitude programming current (e.g., I2 (min)) may be sufficient to set “soft” devices to the desired low resistance state, yet be ineffective at setting “typical” or “hard” devices to the low resistance state. The result is that the yield is less than satisfactory. Finally, the fixed-magnitude set pulse approach of the '719 patent does not address reliability concerns. The programming characteristics of the various memory devices change over the lifetime of the memory. To ensure that the devices are capable of being repeatedly programmed to the desired low resistance state over the lifetime of the memory, lower or higher magnitude set pulses may be necessary as the memory ages. Unfortunately, fixed magnitude set pulses do not afford this desired flexibility.

U.S. Pat. No. 6,570,784 to Lowrey (hereinafter referred to as “the '784 patent”) discloses an improvement to the programming method disclosed in the '719 patent. According to the '784 patent method, the set pulse is shaped so that it ramps down, from a maximum current I_{2(MAX)} at the beginning of the pulse, to a minimum current I_{2(MIN)} at the end of the pulse. (See FIG. 3B here, which is a reproduction of FIG. 2 in the '784 patent.) Unlike the method disclosed in the '719 patent, the '784 patent method ensures that all cells of the memory receive a current that is at least as high as an optimum temperature Tₒₚₜ required to set the memory devices to crystalline low resistance states. Hence, according to the '784 patent inventors, use of a ramped pulse leads to better crystallization of more devices, despite device-to-device fabrication process and material variations. While this may be true, the '784 patent still has a number of drawbacks.

First, sweeping the current from I_{2(MAX)} to I_{2(MIN)} requires a longer than desired programming time. Second, because the set pulse is ramped for a given device, the optimum current magnitude is only applied for a very brief time. Other times the current is either higher than optimum or is lower than optimum. When the programming current is too high (near I_{2(MAX)}), “soft” and “typical” devices (see FIG. 4) are undesirably reset to the amorphous high-resistance state. Too high of a programming current also contributes to unnecessary wear of the devices, thereby reducing their operational lifetime. At the other extreme (near I_{2(MIN)}), the programming current has little or no effect on “hard” and “typical” devices (see FIG. 4), and it is difficult or impossible to set these devices to the desired crystalline low resistance state. Indeed, the two programming current extremes are really only useful to program devices at the soft and hard tails of the population, which together typically constitute only about 1% of the entire device population on a given chip. Finally, as in the '719 patent, the set pulse duration is fixed. Having a fixed duration set pulse is not always effective since, as shown in FIG. 5, the resistance of a programmed PCD depends not just on the programming current magnitude, but also on the duration of the programming pulse.

Given the foregoing limitations and restrictions of the known prior art, it would be desirable to have a method and apparatus for programming PCDs that better addresses fabrication yields; is more capable of uniformly setting and controlling the low resistance states of a plurality of soft and hard PCDs to within precise predetermined ranges; and which adapts to variations in performance changes of individual PCDs as the PCDs age over their lifetime.

### BRIEF SUMMARY OF THE INVENTION

Methods and apparatus for programming phase change devices (PCDs) to low resistance states are disclosed. According to an exemplary method, a control circuit operates to select a pulse generator, which is operable to generate and apply a first sequence of programming pulses (i.e., “set” pulses) to a PCD. After each set pulse of the first sequence of programming pulses is applied, the control circuit operates to deselect the pulse generator and couple a verify circuit to the PCD. The verify circuit operates to determine whether the resistance to which the PCD has been programmed satisfies a predetermined target resistance value or falls within a predetermined target resistance range. If the verify circuit determines that the programmed resistance of the PCD satisfies the target specification, the method ends. If the target specification is not satisfied, the control circuit determines whether a predefined maximum number of set pulses of the first sequence of programming pulses has been exceeded. If the predefined maximum has not been exceeded, the next set pulse in the sequence is applied to the PCD and the programmed resistance is once again measured. If the programmed resistance of the PCD does not satisfy the target resistance specification after all of the set pulses of the first sequence have been applied, set pulses from a one or more subsequent sequences of set pulses having different magnitudes and/or durations may be applied to the PCD, and the process continued in the manner the first sequence of set pulses was applied. A maximum allowable programming time can be set to end the method, if multiple attempts to program the PCD to the target resistance specification have shown to be unsuccessful.

Further features and advantages of the present invention, as well as the structure and operation of various embodiments of the present invention, are described in detail below with respect to accompanying drawings, in which like reference numbers are used to indicate identical or functionally similar elements.

### BRIEF DESCRIPTION OF THE DRAWINGS

FIG. 1 is a simplified diagram of a phase change device;

FIG. 2 is a graph illustrating the low resistance crystalline state and the high resistance amorphous state of a phase change device;

FIG. 3A is a graph showing the characteristics of a set pulse used to program a phase change device, according to a prior art method;

FIG. 3B is a graph showing the characteristics of a set pulse used to program a phase change device, according to another prior art method;

FIG. 4 is a graph illustrating the resistance after programming of soft, typical and hard phase change devices for different programming currents;

FIG. 5 is a graph of the resistance after programming of a phase change device versus programming current for various programming pulses of different durations;

FIG. 6 is a block diagram of an exemplary programming apparatus for programming a phase change device, according to an embodiment of the present invention;

FIG. 7 is a schematic drawing of an exemplary verify circuit, which can be used in the programming apparatus shown in FIG. 6;

FIG. 8 is a flow chart illustrating an exemplary method of programming a phase change device to a low resistance state, according to an embodiment of the present invention;

FIG. 9 is a schematic drawing of an exemplary current magnitude adjustment circuit, which may be used to adjust the current magnitude of a programming pulse, according to an aspect of the present invention;

FIG. 10 is a schematic drawing of a duration control circuit, which can be used to adjust the duration of a programming pulse, according to an aspect of the present invention; and

FIG. 11 is a drawing illustrating a series of programming pulse sequences, according to an exemplary embodiment of the present invention.

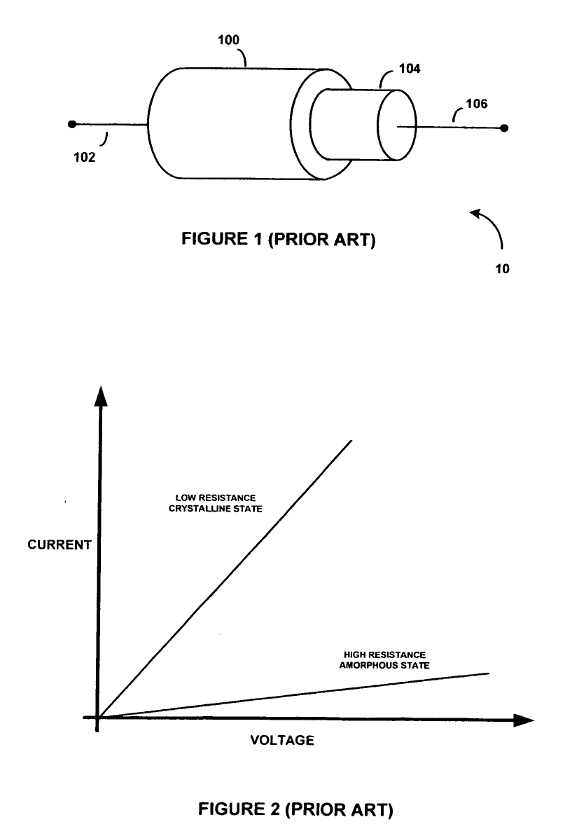

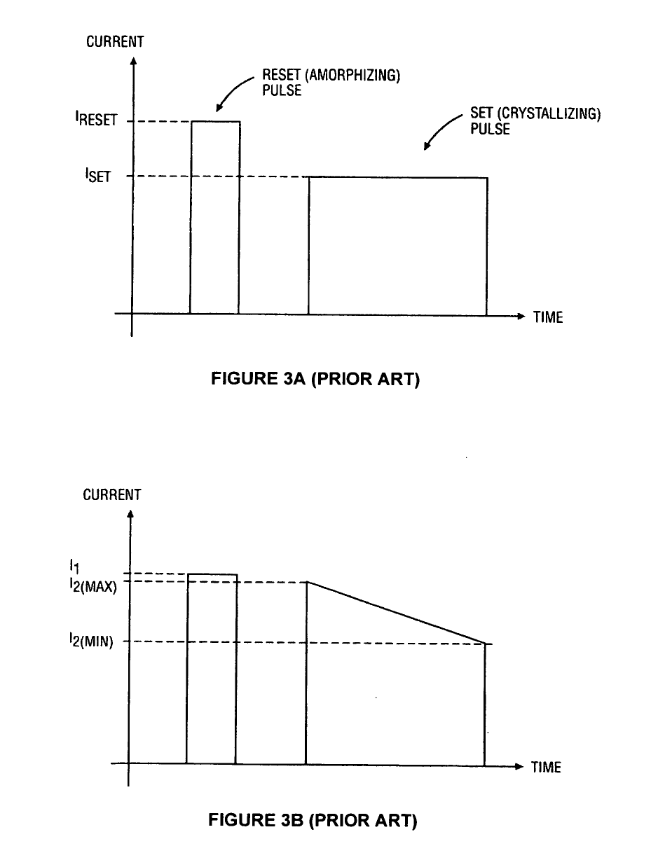

### DETAILED DESCRIPTION OF THE INVENTION

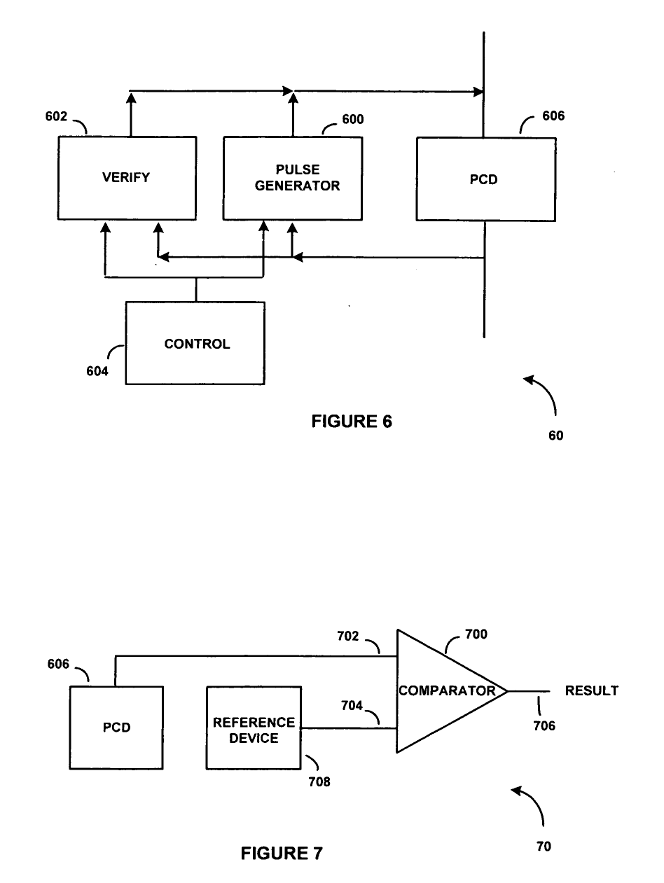

Referring to FIG. 6, there is shown a block diagram of an exemplary apparatus 60 for programming a phase change device (PCD), according to an embodiment of the present invention. The programming apparatus 60 is operable to program a PCD to a low resistance state from any other resistance state, according to a novel programming method of the present invention. The programming apparatus 60 comprises a pulse generator 600, a verify circuit 602, a control circuit 604. A PCD to be programmed 606 is selectively coupled to either the pulse generator 600 or the verify circuit 602. As explained in detail below, the novel programming method of the present invention comprises one or more sequences of two principle operations —a set operation and a verify operation. The control circuit 604 is operable to selectively couple the pulse generator 600 and verify circuit 602 to the PCD 606 during application of the programming method, which is described in detail below. According to an aspect of the invention, the control operations performed by the control circuit 604 are based on observed device behavior, so that program time and possibilities of failure are minimized.

FIG. 7 is a schematic drawing of an exemplary verify circuit 70, which may be used to implement the verify circuit 602 in the programming apparatus 60 in FIG. 6. The verify circuit 70 comprises a comparator 700 having two inputs 702, 704 and an output 706. A first input 702 is coupled to the PCD 606 when the control circuit 604 has selected the verify circuit 60. The second input 704 of the comparator 700 is coupled to a reference device 708, which may comprise a pre-programmed reference PCD having known current characteristics, or any other suitable device capable of providing a reference. Other verify techniques such as, for example, use of a voltage reference may also be employed.

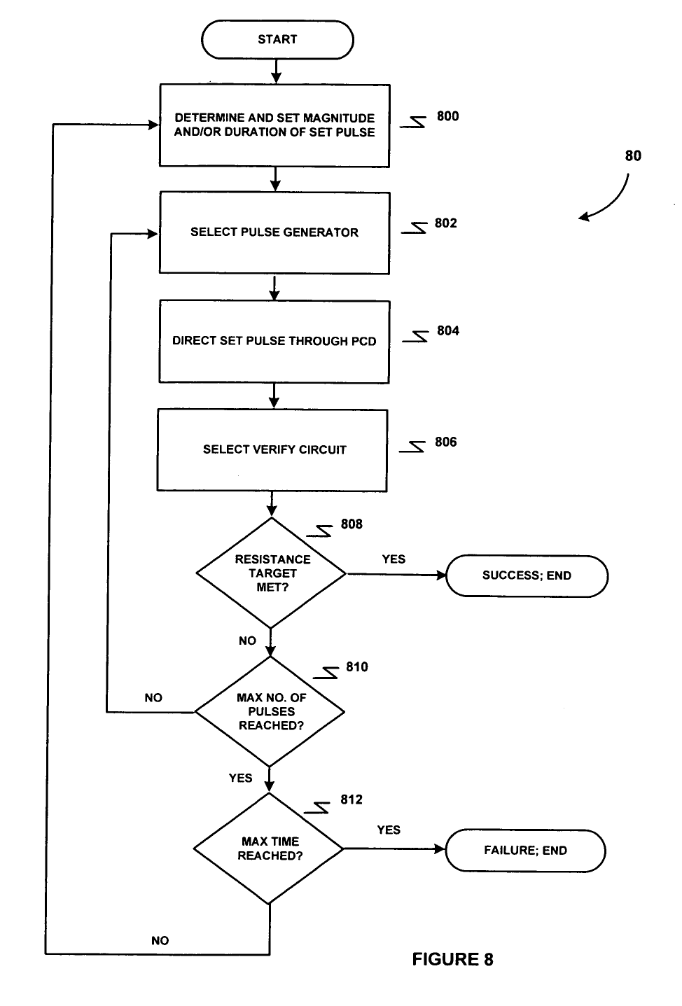

FIG. 8 is a flow chart illustrating a method 80 of programming a PCD to a low resistance state, according to an embodiment of the present invention. While the various steps of the method 80 are shown as occurring in a particular ordered sequence of steps, this order is only exemplary and one or more of the steps may be performed before or after one or more other steps of the method 80. At step 800 the magnitude (e.g., 350 μA) and/or duration (e.g., 100 ns) of a programming current pulse (i.e., set pulse) to be applied to the PCD 606 is determined and set. Those of ordinary skill in the art will understand that the actual magnitude and pulse duration may depend on the particular technology employed. So, for example, the set pulse magnitude selected could vary from a few tens of microamperes to a few milliamperes, and the set pulse duration selected could vary from a few nanoseconds to a few microseconds. At step 802 the control circuit 604 operates to couple the pulse generator 600 to the PCD 606. Then, at step 804, in a first attempt to program the PCD 606 to a low resistance state, the pulse generator 600 directs the set pulse having the characteristics defined in step 800 through the PCD 606. After the set pulse has completely passed through the PCD 606, at step 806 the control circuit 604 operates to deselect the pulse generator 600 and couple the verify circuit 602 to the PCD 606. Once coupled to the PCD 606, at step 808 the verify circuit 602, using for example the reference device 708 of the comparator in the exemplary verify circuit 70 in FIG. 7, determines whether the resistance value of the PCD 606 satisfies a predetermined target resistance or falls within a range of predetermined acceptable resistances. If a test current is passed through the PCD 606 during the verification process, the current is maintained at a relatively lower magnitude of the programming current, so that the test current does not affect the set state established during the programming steps. If the verify circuit 602 determines that the initial set pulse has succeeded in setting the PCD 606 to the target resistance, the method 80 is complete. If, on the other hand, the verify circuit 602 determines that the initial set pulse was unsuccessful in setting the PCD 606 to the target resistance, the method continues at the decision in step 810.

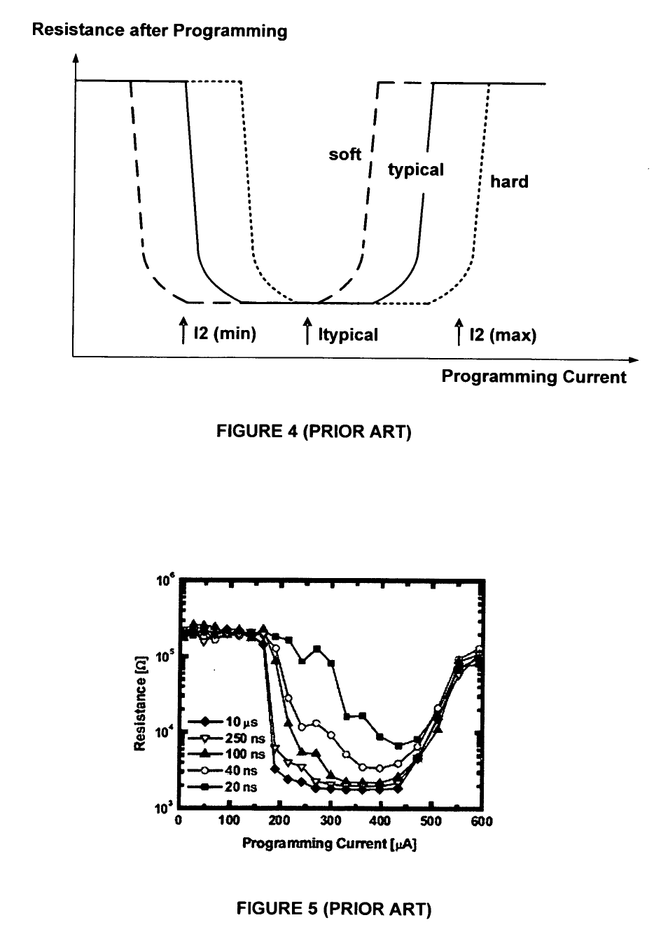

According to an exemplary aspect of the method 80, if the PCD 606 is determined not to have been programmed to the predetermined target resistance, one or more subsequent set pulses in a sequence of set pulses having the same magnitude and pulse duration may be applied to the PCD 606, in an attempt to lower the resistance to the predetermined target resistance. After each time the verify circuit determines that the resistance of the PCD 606 has not been set to the predetermined target resistance, a decision at step 810 determines whether a maximum allowable number of set pulses in the sequence have been applied. If “no”, steps 802 through 808 are repeated until the desired target resistance is achieved or the maximum allowable number of pulses in the sequence has been applied. If the maximum number of set pulses in the sequence is determined to have been applied by the decision at step 810 (i.e., “yes” at step 810), it is likely that the PCD 606 is not typical. In other words, an unsuccessful setting of the PCD 606 to the desired low resistance target state is an indication that the PCD 606 is a soft device, a hard device (see FIG. 4 above), or possibly a defective device.

According to an exemplary aspect of the method 80, the magnitude and/or pulse duration of the set pulse may be adjusted to form one or more subsequent sequences of set pulses, if the decision at step 810 determines that the maximum allowable number of original set pulses of the initial sequence have been applied. Before any adjustments to the magnitude or pulse duration are effected, however, a decision at step 812 queries as to whether a predefined maximum allowable programming time has been exceeded. A maximum allowable programming time may be necessary, given that certain PCDs may be defective or otherwise incapable of being programmed to the desired target resistance. Accordingly, at step 812, if it is determined that a maximum allowable programming time has been exceeded, the method 80 terminates, and the PCD 606 is sorted out as a failed device. If, on the other hand, it is determined that the maximum allowable programming time has not been exceeded, the method branches back to step 800.

If the decisions at steps 810 and 812 determine that the PCD 606 is either a soft device or a hard device, and that the maximum allowable programming time has not been exceeded, at step 800 the magnitude of the set pulses is adjusted. Whether the set pulse magnitude should be increased or decreased depends on whether the PCD being programmed 606 is a soft device or is a hard device. Because it cannot be definitively determined whether the PCD 606 is a soft device or is a hard device, an assumption is made that it is a soft device. As was shown in FIG. 4, compared to hard devices, soft devices are capable of being programmed to a low resistance state using a lower magnitude set pulse. Adjusting the set pulse magnitude to a lower magnitude current (e.g., 250 μA) is preferred, since it avoids the risk of damaging or melting the device. It also avoids the potential problem of inadvertently programming softer devices into the amorphizing range (see FIG. 4), which has the effect of increasing the device resistance. Nevertheless, whereas the adjustment to a lower magnitude is preferred, it is not mandatory, and the method 80 could also be continued by increasing the magnitude of the set pulse.

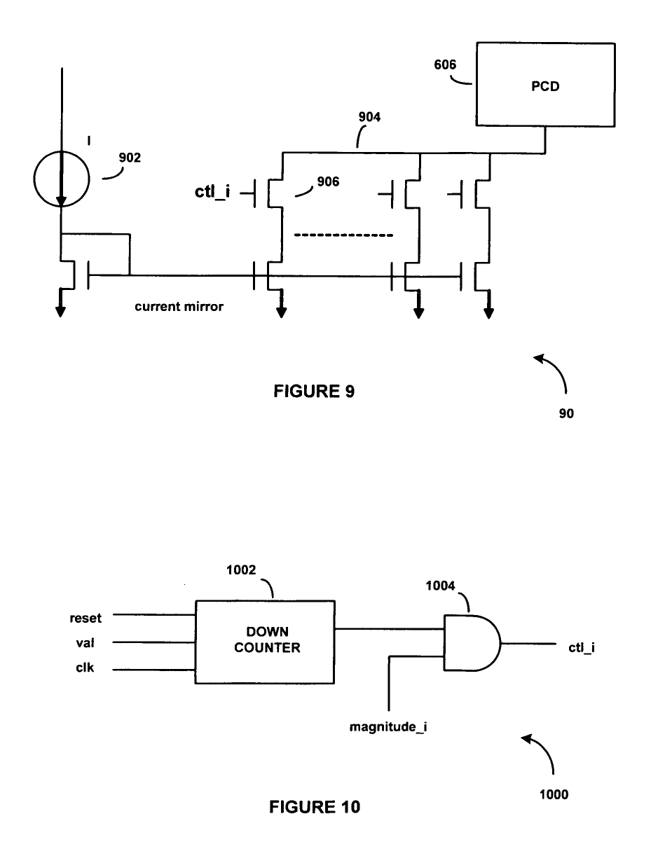

FIG. 9 is a schematic diagram of an exemplary current magnitude adjustment circuit 90, which may be used to adjust the current magnitude of the set pulse in step 800. The current magnitude adjustment circuit 90 comprises a unit current generator 902 and one or more current mirrors 904 having predetermined multiplication ratios. The desired total programming current pulse magnitude (i.e., set pulse magnitude) is achieved by turning on or turning off control devices 906 associated with each current mirror 904. By turning one or more of the control devices 906 off, the total programming current pulse magnitude is decreased. Conversely, by turning one or more of the control devices 906 on, the total programming current pulse magnitude is increased.

As alluded to above, the duration of the set pulse may also (or alternatively) be adjusted at step 800. FIG. 10 is a schematic drawing of duration control circuit 1000, which can be used to adjust the duration of the set pulse. The duration control circuit 1000 comprises a down counter 1002 and an AND logic gate 1004. The down counter has an output that is coupled to a first input of the AND gate 1004. A second input of the AND gate 1004 is configured to receive logic high signal (identified in FIG. 4 as “magnitude_i”). The down counter 1002 also includes a clock input (“clk”) configured to receive a clock signal of a predetermined frequency, a reset input configured to receive a reset signal defining the start of the set pulse, and a value (“val”) input, which may comprise several input signals for the required multiple of clock period. The output of the down counter 1002 remains high as the counter 1002 counts from the beginning of the reset signal until it counts down to the required time interval defining the desired pulse duration. Because the magnitude_i input also receives a high signal, the output of the AND gate 1004 (labeled “ctl_i” in the drawing), which is coupled to one or more of the control device inputs in the current magnitude adjustment circuit 90 in FIG. 9, also remains high during this time interval. Once the counter 1002 reaches the end of the count down time interval, the clock signal causes the output of the counter 1002 to go low, thereby causing the output of the AND gate to also drop low.

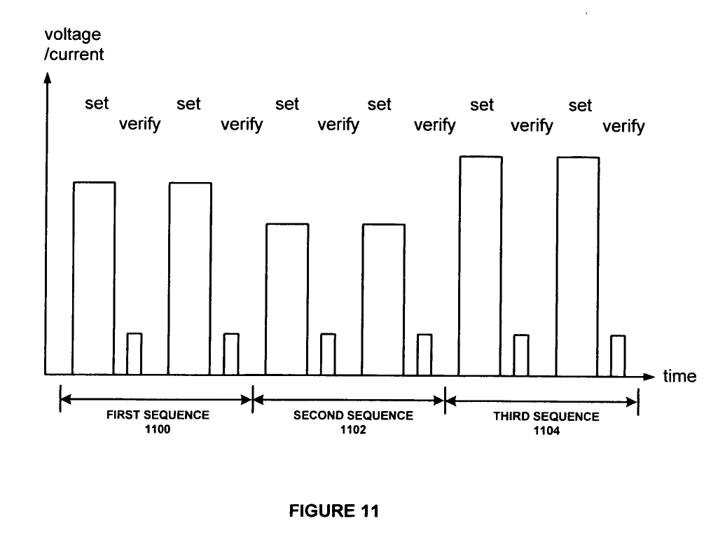

After the magnitude and/or duration of the set pulse have/has been adjusted, at step 802 the control circuit 604 operates to couple the pulse generator 600 to the PCD 606. FIG. 11 shows an example of the programming sequence. A first sequence 1100 of two initial set pulses described above has pulses with the original magnitude of (350 μA) and duration (100 ns). The first sequence 1100 of two initial set pulses is followed by a second sequence 1102 of two adjusted set pulses, each having a magnitude of, for example, 250 μA.

After the control circuit 604 couples the pulse generator 600 to the PCD 606, at step 804 the pulse generator 600 directs the first reduced-magnitude set pulse of the second sequence 1102 of set pulses through the PCD 606. After the first reduced-magnitude set pulse has completely passed through the PCD 606, at step 806 the control circuit 604 operates to deselect the pulse generator 600 and couple the verify circuit 602 to the PCD 606. Once coupled to the PCD 606, at step 808 the verify circuit 602 determines whether the resistance value of the PCD 606 satisfies the predetermined target resistance. If the verify circuit 602 determines that the modified set pulse has succeeded in setting the PCD 606 to the target resistance, the method 80 is complete. If, on the other hand, the verify circuit 602 determines that the modified set pulse was unsuccessful in setting the PCD 606 to the target resistance, the method continues at the decision in step 810. The decision at step 810 determines whether a maximum allowable number of set pulses in the second sequence 1102 has been applied. If “no”, steps 802 through 808 are repeated until the desired target resistance is achieved or until the maximum allowable number of pulses in the second sequence 1102 has been applied.

The decision at step 812 then once again queries as to whether the predefined maximum allowable programming time has been exceeded. If “yes”, the method 80 terminates, and the PCD 606 is sorted out as a failed device. If “no”, i.e., the maximum allowable programming time has not been exceeded, the method branches back to step 800, where it is assumed that the PCD 606 is a hard device. At step 800, the set pulse magnitude is increased (to, for example, 450 μA) and the process described above is repeated above with an increased magnitude sequence of set pulses (see sequence 1104 in FIG. 11).

While the method 80 has been described in terms of a specific exemplary programming sequence, those of ordinary skill in the art will readily appreciate and understand that various modifications to the method can be used to successfully program a PCD to a low resistance state. For example, instead of fixing the duration of set pulses in a sequence of set pulses in the hundreds of nanoseconds, a sequence of set pulses having shorter but increasing durations (e.g., such as a few nanoseconds to a few tens of nanoseconds) may be generated and applied. The sequence of shorter pulses of increasing pulse duration may then be used to precisely set the desired low resistance value. Second, different pulse durations within a sequence or among sequences of set pulses may also be used, depending on the application and programming requirements. Third, the number of different set pulse magnitudes can be modified within a programming sequence or among a plurality of programming sequences. For example, instead of using a series or sequence of set pulses, if the uniformity of the technology is good, a single or multiple large magnitude set pulses may be applied to reduce programming time. Accordingly, if a plurality of PCDs fabricated from a particular technology across a die or chip is known to have very uniform material and operating characteristics, a single large magnitude pulse may be sufficient to set one or more of the plurality of PCDs to their low resistance states. The required set pulse magnitude and duration can be characterized in advance using a reference PCD, after which the predetermined set pulse magnitude and duration can be applied to selected ones of the plurality of PCDs. Indeed, if the fabrication and material is very uniform, the verify steps described in the method 80 may not be necessary.

Finally, the methods described above, including the one or more possible variations just discussed, can be combined to enable multiple level resistance states. Using the data in FIG. 5, for example, it is seen that the set and reset states discussed above occupy resistance ranges of <3 kΩ and >100 kΩ, respectively. These two resistance ranges are useful for binary memory. However, a tri-level resistance device can be implemented by utilizing the resistance values between 3 kΩ and 100 kΩ. Further, a two-bit storage device can be realized by programming the PCD to one of four different resistance values (e.g., <3 kΩ, 6-10 kΩ, 20-50 kΩ, and >100 kΩ), using the data in FIG. 5 as an example. To achieve resistance values in these four ranges, a short-duration pulse in the range of a few nanoseconds to a few tens of nanoseconds may be applied, while the magnitudes of pulses in a sequence of the applied pulses are increased from a lower magnitude to a higher magnitude.

Although the present invention has been described with reference to specific embodiments thereof, these embodiments are merely illustrative, and not restrictive, of the present invention. Additionally, various modifications or changes to the specifically disclosed exemplary embodiments will be suggested to persons skilled in the art and are to be included within the spirit and purview of this application and scope of the appended claims.

What is claimed is:

1. A method of programming a phase change device to a low resistance state, comprising:
applying one or more first programming pulses having a predetermined magnitude and/or duration to a phase change device;
determining whether a programmed resistance of said phase change device is in accordance with a predetermined target resistance specification; and
if said programmed resistance is not in accordance with said predetermined target resistance specification, applying one or more second programming pulses having a magnitude and/or duration different than the magnitude and/or duration of said one or more first programming pulses to said phase change device.

2. The method of claim 1 wherein determining whether a programmed resistance of said phase change device is in accordance with a predetermined target resistance specification is performed after each of said one or more first programming pulses is applied to said phase change device.

3. The method of claim 1 wherein determining whether a programmed resistance of said phase change device is in accordance with a predetermined target resistance specification is performed after each one of said one or more second programming pulses is applied to said phase change device.

4. The method of claim 1 wherein said one or more first programming pulses comprises a plurality of programming pulses, each programming pulse of said plurality of programming pulses having the same magnitude.

5. The method of claim 1 wherein said one or more first programming pulses comprises a plurality of programming pulses, each programming pulse of said plurality of programming pulses having the same duration.

6. The method of claim 1 wherein said one or more first programming pulses comprises a plurality of programming pulses, at least two programming pulses of said plurality of programming pulses having different magnitudes and/or durations.

7. A method of programming a phase change device, comprising:
configuring a phase change device to receive one or more initial programming pulses;
applying one or more initial programming pulses to said phase change device;
configuring said phase change device to receive one or more subsequent programming pulses;
applying one or more subsequent programming pulses to said phase change device, at least one of said one or more subsequent programming pulses having a different magnitude than a magnitude of at least one of said one or more initial programming pulses.

8. The method of claim 7, further comprising determining whether a programmed resistance of said phase change device is less than a predetermined target resistance, after applying one or more of said one or more initial programming pulses.

9. The method of claim 7, further comprising determining whether a programmed resistance of said phase change device is less than a predetermined target resistance, after applying one or more of said one or more initial programming pulses.

10. The method of claim 7 wherein said one or more initial programming pulses comprises a plurality of initial programming pulses, each programming pulse of said plurality of initial programming pulses having the same magnitude.

11. The method of claim 7 wherein said one or more initial programming pulses comprises a plurality of initial programming pulses, each programming pulse of said plurality of initial programming pulses having the same duration.

12. The method of claim 7 wherein said one or more initial programming pulses comprises a plurality of initial programming pulses, at least two programming pulses of said plurality of initial programming pulses having different magnitudes and/or durations.

13. A method of programming a phase change device, comprising:
configuring a phase change device to receive a sequence of programming pulses; and
applying a sequence of programming pulses to said phase change device.

14. The method of claim 13 wherein at least two pulses of said sequence of programming pulses have the same magnitude.

15. The method of claim 13 wherein at least two pulses of said sequence of programming pulses have different durations.

16. The method of claim 13, further comprising:
determining whether a programmed resistance of said phase change device satisfies a target resistance specification following application of each pulse of said sequence of programming pulses; and
if it is determined that said phase change device does not have a programmed resistance satisfying said target resistance specification, applying a second sequence of programming pulses to said phase change device, said second sequence of programming pulses having at least one pulse with a magnitude and/or duration that is different than a magnitude and/or duration of at least one pulse of the first sequence of programming pulses.

17. An apparatus for programming a phase change device comprising:
a programming pulse generator operable to generate a sequence of programming pulses and adapted to apply said sequence of programming pulses to a phase change device; and
a verify circuit operable to determine whether a programmed resistance of a phase change device being programmed by said sequence of programming pulses satisfies a target resistance specification.

18. The apparatus of claim 17, further comprising a control circuit operable to selectively couple either said programming pulse generator or said verify circuit to a phase change device.

19. The apparatus of claim 17 wherein said verify circuit comprises:
a reference device; and
means for determining whether the programmed resistance of said phase change device satisfies a predetermined target resistance specification defined by said reference device.

20. The apparatus of claim 19 wherein said reference device comprises a phase change device.
